(19) United States
(12) Patent Application Publication
(10) Pub. No.: US 2025/0030432 A1
(43) Pub. Date: Jan. 23, 2025

(54) ANALOG-TO-DIGITAL CONVERTERS AND METHODS FOR SETTLING OF THE REFERENCE VOLTAGE IN ANALOG-TO-DIGITAL CONVERTERS

(71) Applicant: Intel Corporation, Santa Clara, CA (US)

(72) Inventors: Thomas BROWN, Portland, OR (US); Hariprasad CHANDRAKUMAR, Beaverton, OR (US); Georgios DOGIAMIS, Chandler, AZ (US); Benjamin HERSHBERG, Portland, OR (US)

(21) Appl. No.: 18/355,414

(22) Filed: Jul. 20, 2023

(51) Int. Cl. H03M 1/46; H03M 1/12

(52) U.S. Cl. CPC H03M 1/462; H03M 1/1215

(57) ABSTRACT

Disclosed herein are devices, methods, and systems related to analog-to-digital converters (ADCs), and in particular, to settling the reference voltage in an ADC and to settling the reference voltage in a time-interleaved arrangement of ADCs. A method of settling of a reference voltage in an ADC may include generating, on a reference voltage line, an analog reference voltage, and connecting, at the time of generating the analog reference voltage, a pre-charged capacitor of the ADC to the reference voltage line to reduce a voltage error during the generation of the analog reference voltage.

### TECHNICAL FIELD

Various aspects of this disclosure generally relate to analog-to-digital converters (ADCs), and in particular, to settling the reference voltage in an ADC and to settling the reference voltage in a time-interleaved arrangement of ADCs.

### BACKGROUND

Analog-to-digital converters are frequently used as essential building blocks for high speed wideband (mixed-signal) systems such as serializer/deserializer receivers, cellular base-stations, 5G and 6G high speed communication systems, imaging radar systems and other high-speed IO technologies such as wireless I/O, mmWave I/O, etc.

An ADC may include at least one digital-to-analog converter (DAC) to convert a digital code to an analog signal representing a reference voltage. Typically, each time an ADC converts a bit from a digital code, the reference voltage (VREF) drops briefly. In high speed systems, this voltage difference or error may distort the conversion of the next bit(s), i.e. the reference voltage may take too long to settle, reducing the overall performance of the ADC.

In high speed systems using time-interleaved ADC arrangements/arrays including a plurality of time interleaved ADCs sharing a common reference voltage across all ADC slices, crosstalk may further deteriorate the performance of both an individual slice and of the combined time interleaved ADC arrangement.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. It should be understood that the drawings are diagrammatic and schematic representations of exemplary aspects of the invention, and are neither limitative nor necessarily drawn to scale of the present invention. In the following description, various embodiments of the invention are described with reference to the following drawings, in which:

FIG. 1 shows an exemplary ADC;

FIG. 2 shows an exemplary ADC including a capacitor bank according to some aspects;

FIG. 3 shows a schematic overview of the different signals and current pulses;

FIG. 4 shows an exemplary fast recharge circuit including a charge pump according to some aspects;

FIG. 5 shows an exemplary ADC including a same-cycle error correction circuit according to some aspects;

FIG. 6 shows an exemplary ADC including a multi-cycle error correction circuit according to some aspects;

FIG. 7 shows a schematic overview of reference voltage degradation in TI ADCs;

FIG. 8 shows an exemplary arrangement of TI ADCs according to some aspects; FIG. 9 shows a flowchart illustrating a method of settling of a reference voltage in an ADC according to some aspects; FIG. 10 shows a flowchart illustrating a method of settling of a reference voltage in a plurality of time-interleaved ADCs sharing a common reference voltage source; and

FIG. 11 shows an exemplary ADC according to some aspects.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The terms “at least one” and “one or more” may be understood to include a numerical quantity greater than or equal to one (e.g., one, two, three, four, [. . . ], etc.). The term “a plurality” may be understood to include a numerical quantity greater than or equal to two (e.g., two, three, four, five, [. . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The phrases “group (of)”, “set (of)”, “collection (of)”, “series (of)”, “sequence (of)”, “grouping (of)”, etc., and the like in the description and in the claims, if any, refer to a quantity equal to or greater than one, i.e., one or more.

The phrase “at least one of” with regard to a group of elements may be used herein to mean at least one element from the group including the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit, and may also be referred to as a “processing circuit,” “processing circuitry,” among others. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality, among others, and conversely that any single processor, controller, or logic circuit detailed herein may be realized as two (or more) separate entities with equivalent functionality, among others.

As used herein, “memory” is understood as a computer-readable medium in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, among others, or any combination thereof. Registers, shift registers, processor registers, data buffers, among others, are also embraced herein by the term memory. The term “software” refers to any type of executable instruction, including firmware.

The term “calculate” encompass both ‘direct’ calculations via a mathematical expression/formula/relationship and ‘indirect’ calculations via lookup or hash tables and other array indexing or searching operations. The term “determine” encompass both ‘direct’ determinations via a mathematical expression/formula/relationship and ‘indirect’ determinations via lookup or hash tables and other array indexing or searching operations.

In the following, examples and embodiments of ADCs and methods for settling the reference voltage of an ADC are described in detail.

In the following exemplary embodiments, the invention is in particular shown and described with reference to successive approximation register ADCs. It should however be understood by those skilled in the art that various changes in form and detail may be made therein, and that the invention can be applied to other types of ADCs, such as e.g. flash ADCs where digital approximations of an input voltage are performed in parallel, pipelined ADCs, delta-sigma ADCs, hybrid ADCs, etc.

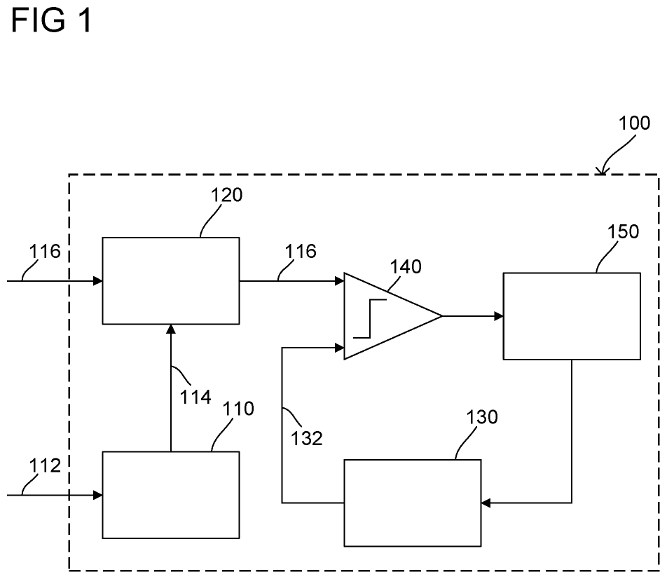

FIG. 1 illustrates an exemplary successive-approximation register (SAR) analog-to-digital converter (ADC) 100. A SAR ADC is a type of ADC that uses a binary search algorithm to convert an analog voltage signal VIN into a corresponding digital representation.

The exemplary SAR ADC 100 includes a clock generator 110, a sampling switch 120, a digital-to-analog converter, DAC, 130, a comparator 140 and a SAR controller 150.

The clock generator 110 is configured to receive an (external) input clock signal 112, to generate a sampling clock signal 114, and to send the sampling clock signal 114 to sampling switch 120.

The sampling switch 120 is configured to receive the sampling clock signal 114 from clock generator 110, and to be switched on when it also receives an (analog) input voltage signal 116 (V_{IN}). The sampling switch 120 may remain switched on until the final digital approximation of the input signal V_{IN}, and then disconnected/reset before conversion of a next input analog voltage. The sampling switch 120 may for example be implemented as a sample and hold circuit. The sampling switch 120 is further configured to send the input voltage 116 (V_{IN}) to comparator 140.

The DAC 130 is configured to receive an n bit digital code/signal from SAR controller 150. The initial digital code is typically selected by the controller as the midpoint of the total possible bit range.

For example, if the DAC has 12 bit resolution, the initial digital code may be set to 0111 1111 1111, which is the midpoint of the range 0000 0000 0000 to 1111 1111 1111.

The digital code is converted by the DAC 130 into an analog reference signal/voltage 132, and transmitted to comparator 140.

The comparator 140 is configured to receive both the input voltage 116 (V_{IN}) from sampling switch 120 and the generated reference voltage VREF on line 132 from DAC 130, to compare the two, thereby determining whether the generated reference voltage 132 is higher or lower than the input voltage 116. The comparator 140 is further configured to transmit the result of the comparison to SAR controller 150.

The SAR controller 150 is configured to determine an initial digital code and to send it to the DAC 130. The SAR controller 150 is further configured to determine each further digital code in a series of digital codes(s) (after the initial code) representing successive digital approximations of the input voltage 116 (V_{IN}). The determination is based on the received comparison results from comparator 140.

The SAR controller 150 typically does a bit-by-bit approximation of the digital code, starting from the most significant bit (MSB) (or from the MSB−1) and setting each bit to either 1 or 0, depending on the comparison result.

For example, the SAR controller 150 may set the MSB to 1 when the result of the comparison outputted by comparator 140 indicates that input voltage 116 (V_{IN}) is higher than the generated reference voltage VREF on line 132, and set it to 0 otherwise. The new digital code is then transmitted to the DAC 130, and the resulting output reference voltage 132 is then again compared to the analog input voltage 116. The SAR controller 150 repeats this procedure until it reaches the least significant bit (LSB) of the digital code.

The SAR controller 150 may further be configured to, once all the bits have been processed/determined, complete one iteration and output the final digital code as the approximate digital representation of the input voltage 116 (V_{IN}).

In ADCs, and in particular in SAR ADCs, the conversion of previous bit(s) typically requires large currents to be drawn from the (common) reference rail 132, causing the reference voltage VREF on the reference rail to drop. To avoid distortions during the conversion of the next bit(s), it is critical for ADCs included in high speed systems that VREF settles quickly.

VREF not settling fast enough may for example degrade the signal-to-noise ratio (SNR), the signal-to-noise distortion ratio (SINAD), and/or the error magnitude vector (EVM) of an ADC in a high speed system.

In high speed systems using time-interleaved (TI) ADC arrangements/arrays including a plurality of time interleaved ADCs sharing a common reference voltage across all ADC slices, crosstalk may further deteriorate the performance of both an individual slice and of the combined TI ADC arrangement.

In particular, in time-interleaved arrangements of ADCs, due to parasitic resistance and inductance voltage drops cumulatively from all slices on the shared reference rail, an array of slices with the reference voltage supplied from the sides of abutted groups of slices may experience a gradient that further degrades the received reference voltage at the inner slices.

In order to minimize reference voltage drops and/or to ensure fast settling of the reference voltage, large current buffers and/or large capacitors can be added to the reference rail.

Typically, combinations of an active buffer amplifier together with a decoupling capacitance (at the output) is used. For example, the decoupling capacitance may be increased to meet the specifications of supplying the required instantaneous charge. An active buffer (e.g. operating in the AB class) may further be used, wherein the active buffer has quiescent current sufficient to meet peak instantaneous current draw and the speed/bandwidth to deliver the current in the settling period of the reference voltage.

To improve the settling of a common VREF in TI arrangements/arrays of ADCs, combinations of the above techniques may be used across groups of TI slices.

However, the above techniques have several drawbacks. Adding decoupling capacitance increases the (silicon) area required, and thus increases circuit costs.

In TI arrangements, larger capacitors also require larger spacing between slices and/or from the ADC array. Active buffers require high power to meet the settling requirements, thus increasing power/current consumption.

Therefore, there is a need to improve the settling of reference voltages in an ADC and in TI ADC arrangements.

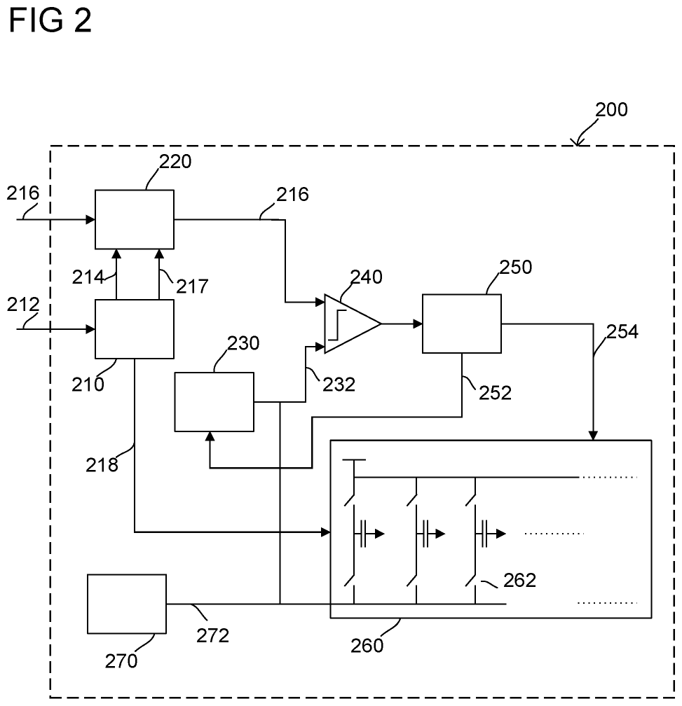

FIG. 2 shows an exemplary ADC 200 including a capacitor bank 260 according to some aspects. ADC 200 may be a SAR ADC including a capacitor bank (array) 260. Alternatively, ADC 200 may include a single capacitor instead of capacitor bank 260.

The ADC 200 includes clock generator 210, sampling switch 220, digital-to-analog converter, DAC, 230, comparator 240, controller 250, capacitor bank 260 and charge voltage source 270. Charge voltage source 270 can alternatively be external to ADC 200.

Clock generator 210 may similar to clock generator 110, and is configured to receive an (external) input clock signal 212, to generate a sampling clock signal 214, and to send the sampling clock signal 214 to sampling switch 220. The clock generator 210 is further configured to send a delayed reset signal (Φᵣ) 218 to sampling switch 220 and to capacitor bank 260.

The sampling switch 220 may be similar to sampling switch 120, and is configured to receive the sampling clock signal 214 from clock generator 210, and to be switched on when it also receives the (analog) input voltage signal 216 (V_{IN}). The sampling switch 220 may remain switched on until the final digital approximation of the input signal V_{IN}, and/or until it receives a (first) reset signal 217 from clock generator 210. The sampling switch 220 may for example be implemented as a sample and hold circuit. The sampling switch 220 is further configured to send input voltage 216 (V_{IN}) to comparator 240.

DAC 230 may be the same as DAC 130, and is configured to receive an n bit digital code/signal 252 from controller 250. DAC 230 may for example be implemented as a capacitive DAC.

The received digital code is converted by DAC 230 into an analog reference signal/voltage VREF which is outputted on a line or rail 232 and transmitted to comparator 240.

The comparator 240 may be the same as comparator 140, and is configured to receive both the input voltage 216 (V_{IN}) from sampling switch 220 and the generated reference voltage VREF on line 232 from DAC 230, to compare the two, thereby determining whether the generated reference voltage on line 232 is higher or lower than the input voltage 216. The comparator 240 is further configured to transmit the result of the comparison to controller 250.

The controller 250 may be similar and/or the same as SAR controller 150, and is configured to determine an initial digital code and to send it to the DAC 230. The controller 250 is further configured to determine each further digital code in a series of digital codes(s) (after the initial code) representing successive digital approximations of the input voltage 216 (V_{IN}). The determination is based on the received comparison result from comparator 240.

The controller 250 may further be configured to, once all the bits have been processed/determined, complete one iteration and output the final digital code as the approximate digital representation of the input voltage 216 (V_{IN}).

The controller 250 may include circuitry configured to detect and keep track of which bit is currently being processed by the DAC 230. Controller 250 may further be configured to keep track of the precise timing of when each bit is processed. Controller 250 may for example include a latch and/or a memory (not shown in FIG. 2) to keep track of the processed bits (ranging from MSB to LSB).

Capacitor bank 260 includes a plurality of pre-charged capacitors. The capacitor bank 260 may for example include n+1 pre-charged capacitors, wherein n is the resolution of the ADC. The capacitors of capacitor bank 260 are pre-charged to a voltage equal to the reference voltage to be generated, or alternatively to a higher voltage supply (V^{DD1}) than the reference voltage (VREF). Capacitor bank 260 further includes a plurality of switches 262. Capacitor bank 260 may have a long settling period and relaxed requirements compared to other parts of ADC 200. Capacitor bank 260 is further configured to be controlled and synchronized by controller 250.

Controller 250 is configured to control the switches 262 to pre-charge one or more capacitors of capacitor bank 260 from a charge voltage source 270 through voltage line 272, which is also connected to the reference voltage line 232.

The charge voltage source 270 may be configured to provide a voltage equal (at least in substance) to the reference voltage to be generated. In particular, the charge voltage source 270 may be implemented by a programmable source of voltage configured to provide a voltage equal to the analog reference voltage generated by the ADC 200. The charge voltage source 270 may alternatively be configured to provide a voltage higher than the analog reference voltage to be generated, which may accelerate settling of the analog reference voltage on line 232. Charge voltage source 270 may be an external supply and not be part of ADC 200 (not shown in FIG. 2). Furthermore, a buffer may be placed between charge voltage source 270 and ADC 200 (not shown in FIG. 2).

The capacitors included in capacitor bank 260 may have different capacitances and/or may be pre-charged to different charge levels. The capacitors may be pre-charged to a higher voltage than the reference voltage to be generated by using a voltage booster as source of charge voltage (not shown in FIG. 2). Furthermore, the capacitance values of the capacitors may be (pre-) calibrated during production and/or in the laboratory.

In the following, capacitor bank 260 may also be referred to as “fast recharge circuit” 260.

Controller 250 is configured to select one (or more) pre-charged capacitor(s) from capacitor bank 260, and to connect the selected capacitor(s) on the common reference voltage line 232 by means of switches 262.

Controller 250 is configured to send (delay) signals 254 (signals Φ₀, Φ₁, . . . ; Φₙ) to capacitor bank 260 in order to connect the pre-charged capacitors on reference voltage line 232 at a precise time. Controller 250 is configured to detect and track each bit processed by the DAC 230, and based on timing and on the bit value (and/or the bit position in the digital code) to synchronously (and accurately) connect one (or more) selected pre-charged capacitor(s) of capacitor bank 260 onto the reference voltage line 232. Controller 250 may for example connect the selected one (or more) pre-charged capacitor(s) right before the conversion of a next bit by DAC 230, thereby precisely providing the charge level needed at the precise/exact time it is needed.

Capacitor bank 260 may further be configured to receive a delayed reset signal 218 (Φᵣ) from clock generator 210, or alternatively from controller 250 (not shown in FIG. 2) in order to switch off and/or discharge a designated capacitor. Alternatively, controller 250 may be configured to switch the designated capacitor on or off. The delayed reset signal (Φᵣ) 218 allows for a reset phase before a next sampling phase and/or before each individual bit.

When compared to ADC 100, ADC 200 allows to synchronously and precisely current boost the reference voltage just before the conversion of the following bit(s), minimizing the VREF voltage drops and/or improving the settling of VREF. The selected pre-charged capacitor(s) from the fast recharge circuit 260 provides a matched current impulse to the current drawn by the ADC for the conversion.

An ADC such as exemplary ADC 200 allows to save power and area by reducing the active buffer requirements to only DC average current replenishment and smaller decoupling capacitors at the active buffer output. This may in turn allows faster conversion rates at higher resolution where reference settling speed and accuracy of the ADC would else limit the overall system.

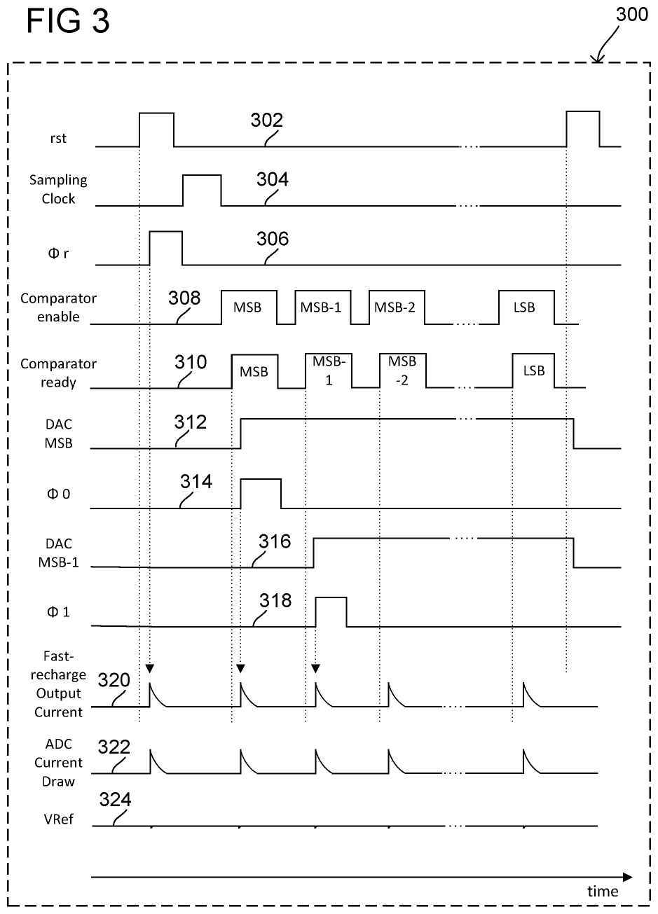

The event (bit) decision driven timing of switching the pre-charged capacitors onto reference voltage line 232, and the matched current pulses are illustrated in FIG. 3.

FIG. 3 shows a schematic overview 300 of the different signals and current pulses of exemplary ADC 200 over time.

As can be seen in FIG. 3, a reset signal 302 is received by ADC 200, (e.g. generated by clock generator 210), instructing the reset of sampling switch 220.

Then sampling switch 220 receives sampling clock signal 304, indicating the start of the (next) sampling phase. In 306, a delayed reset signal (Φᵣ) (corresponding to delayed reset signal 218) is received by fast recharge circuit 260.

In 308, comparator 240 is enabled, and after a short delay, is ready for operation in 310. The DAC 230 starts the processing of a digital code, bit-by-bit, starting from the MSB in 312 (then MSB−1 in 316, etc.)

The controller 250 is configured to send (delay) signals 254 (Φ₀, Φ₁, . . . , Φₙ), whereby Φ₀ and Φ₁ correspond to signals 314 and 318 in FIG. 3, to the fast recharge circuit 260, thereby selecting and connecting the corresponding one (or more) pre-charged capacitor(s) from the fast recharge circuit 260 on the reference voltage line 232 at the precise time (or just before) processing of a bit by the DAC 230. The controller 250 (and/or clock generator 210) is further configured to send delayed reset signal (Φᵣ) 306 to fast recharge circuit 260.

The current drawn by the ADC 200 over time is shown in 322. As can be seen in FIG. 3, when the comparator 240 is enabled and ready, and when DAC 230 starts processing of a bit of digital code (e.g. MSB or MSB−1), the current drawn by the ADC spikes upwards. The current drawn by the ADC also spikes upwards at the start of a reset phase.

The output current from the fast recharge circuit is shown in 320. As can be seen in FIG. 3, by selecting and connecting corresponding one (or more) pre-charged capacitor(s) from the fast recharge circuit 260 on the reference voltage line 232 at the time that the DAC starts processing of a bit of digital code and at the start of a reset phase (via delayed reset signal 306), the current pulse from the output current of the fast recharge circuit 260 synchronously matches the pulse of the ADC current draw.

The reference voltage over time is shown in 324. As a result of matching the current pulses, the V_{REF} voltage drops are minimized, and VREF remains (almost) constant over time, and in particular does not drop significantly every time the current drawn by the ADC spikes.

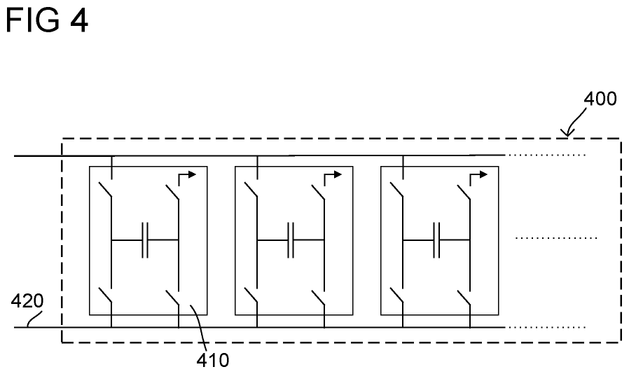

FIG. 4 shows a fast recharge circuit 400 that can be operated as a charge pump as an alternative to the fast recharge circuit 260 of FIG. 2. This provides a means to use a charge voltage source (power supply) that is only slightly above the reference voltage or below it.

Fast recharge circuit 400 includes additional switches 410 to allow charge pump operation. The switches 410 help maintain the time-alignment of the circuit with the other parts of the ADC, such as the comparator and DAC. Voltage 420 represents the lower charge voltage (power supply) to boost which provides the charge replenishment source.

In fast recharge circuit 400, differently weighted (pre-charged) capacitor values are used than in the fast recharge circuit 260, in order to balance the charge added with the charge consumed.

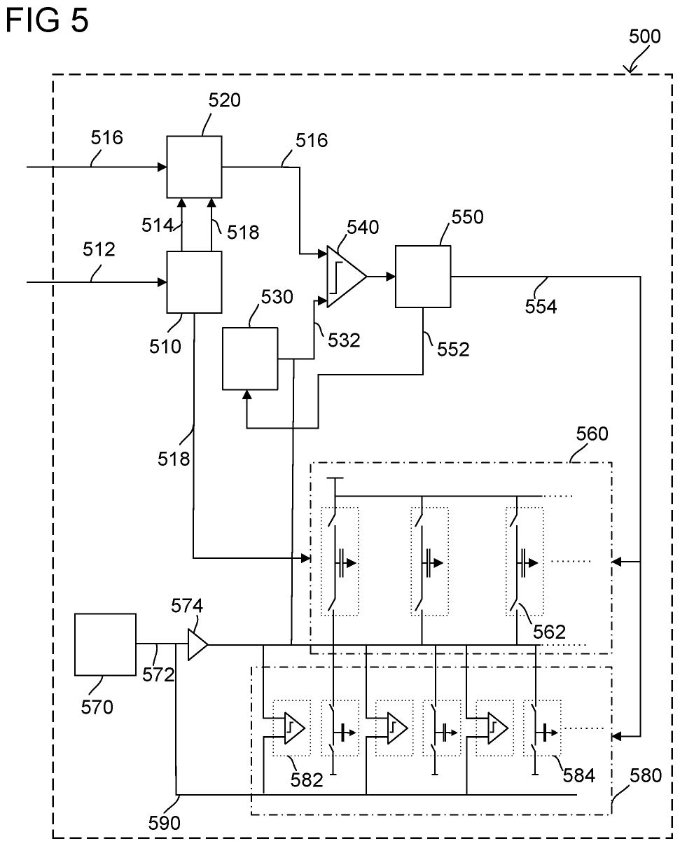

FIG. 5 shows an exemplary ADC 500 including a same-cycle error correction circuit 580.

The ADC 500 includes clock generator 510, sampling switch 520, digital-to-analog converter, DAC, 530, comparator 540, controller 550, capacitor bank 560, charge voltage source 570 and same-cycle error correction circuit 580. ADC 500 may be configured similarly as ADC 200. ADC 500 may be a SAR ADC. As an alternative, charge voltage source 570 may be an external voltage source and not part of ADC 500.

Clock generator 510 may be the same as clock generator 210, and is configured to receive an (external) input clock signal 512, to generate a sampling clock signal 514, and to send the sampling clock signal 514 to sampling switch 520. The clock generator 510 is further configured to send a reset signal 518 to sampling switch 520 and to capacitor bank 560.

The sampling switch 520 may be the same as sampling switch 220, and is configured to receive the sampling clock signal 514 from clock generator 510, and to be switched on when it also receives the (analog) input voltage signal 216 (V_{IN}). The sampling switch 520 may remain switched on until the final digital approximation of the input signal V_{IN}, and/or until it receives a reset signal 518 from clock generator 510. The sampling switch 520 may for example be implemented as a sample and hold circuit. The sampling switch 520 is further configured to send input voltage 516 to comparator 540.

DAC 530 may be the same as DAC 130 or 230, and is configured to receive an n bit digital code/signal 552 from controller 550. DAC 530 may for example be implemented as a capacitive DAC.

The received digital code is converted by DAC 530 into an analog reference signal/voltage 532, and transmitted to comparator 540.

The comparator 540 may be the same as comparator 140 or 240, and is configured to receive both the input voltage 516 from sampling switch 520 and the generated reference voltage 532 from DAC 530, to compare the two, thereby determining whether the generated reference voltage 532 is higher or lower than the input voltage 516. The comparator 540 is further configured to transmit the result of the comparison to controller 550.

The controller 550 may be similar to SAR controller 150 or controller 250, and is configured to determine an initial digital code and to send it to the DAC 530. The controller 550 is further configured to determine each further digital code in a series of digital codes(s) (after the initial code) representing successive digital approximations of the input voltage 516. The determination is based on the received comparison result from comparator 540.

The controller 550 may further be configured to, once all the bits have been processed/determined, complete one iteration and output the final digital code as the approximate digital representation of the input voltage 516.

The controller 550 may include circuitry configured to detect and keep track of which bit is currently being processed by the DAC 530. Controller 550 may further be configured to keep track of the precise timing of when each bit is processed. Controller 550 may for example include a latch and/or a memory (not shown in FIG. 5) to keep track of the processed bits (ranging from MSB to LSB).

The controller 550 is configured to send signal 554 (signals Φ₀, Φ₁, . . . ; Φₙ) to capacitor bank 560 in order to connect the pre-charged capacitors on reference voltage line 532. and to same-cycle error correction circuit 580.

The controller 550 is configured to send signal 554 (signals Φ₀, Φ₁, . . . ; Φₙ) to same-cycle error correction circuit 580. Controller 550 is configured to detect and track each bit processed by DAC 530, and based on timing and on the bit value (and/or the bit position in the digital code) to synchronously connect one (or more) selected pre-charged capacitor(s) of capacitor bank 560 onto the reference voltage line 532.

Capacitor bank 560 may be the same as capacitor bank 260, and includes a plurality of pre-charged capacitors. The capacitors of capacitor bank 560 are pre-charged to a voltage equal to VREF. Alternatively, the capacitors of capacitor bank may be pre-charged to higher voltage than VREF.

Capacitor bank 560 further includes a plurality of switches 562. Capacitor bank 560 may have a long settling period and relaxed requirements compared to other parts of ADC 500. Capacitor bank 560 is further configured to be controlled and synchronized by controller 550.

Controller 550 is configured to control the switches 562 to pre-charge one or more capacitors of capacitor bank 560 from charge voltage source 570 on voltage line 572, which is also connected to the reference voltage line 532.

The charge voltage source 570 may be configured to provide a voltage equal to the reference voltage to be generated. In particular, the charge voltage source 570 may be implemented by a programmable source of voltage configured to provide a voltage equal to the analog reference voltage generated by the ADC 500. Active buffer 574 is placed between charge voltage source 570 and ADC 500. Alternatively, charge voltage source 570 may be external to ADC 500 (not shown in FIG. 5).

The same-cycle error correction circuit 580 is configured to correct errors within one sampling cycle, i.e. occurring during the conversion of a single analog input voltage 516. Controller 550 may be configured to control and synchronize error correction circuit 580.

Same-cycle error correction circuit 580 includes a plurality of comparators 582 and (unique) correction capacitors 584. Same-cycle error correction circuit 580 may include a comparator 582 and a (unique) correction capacitor 584 for a single event/bit, for multiple events/bits, and/or for all of the events/bits occurring during a sampling cycle.

Error correction circuit 580 receives signal 554 from controller 550, which corresponds to delayed versions (Φ₀, Φ₁, . . . ; Φₙ) of each event, i.e. of each bit processed by DAC 530. The generated reference voltage VREF on line 532 is then compared to a clean reference on line 590, which is obtained from voltage source 570, via the plurality of comparators 582. The clean reference 590 may be generated by a further (external) voltage source (not shown in FIG. 5). Depending on the comparison result, the correction capacitors 584 may be switched on the reference voltage line 532.

Error correction circuit 580 allows for more accurate voltage reference levels. It may for example correct/adjust errors caused by mismatches in charge added versus charge consumed, errors due to variation in voltage levels, errors due to variations in capacitors, and errors due to other losses.

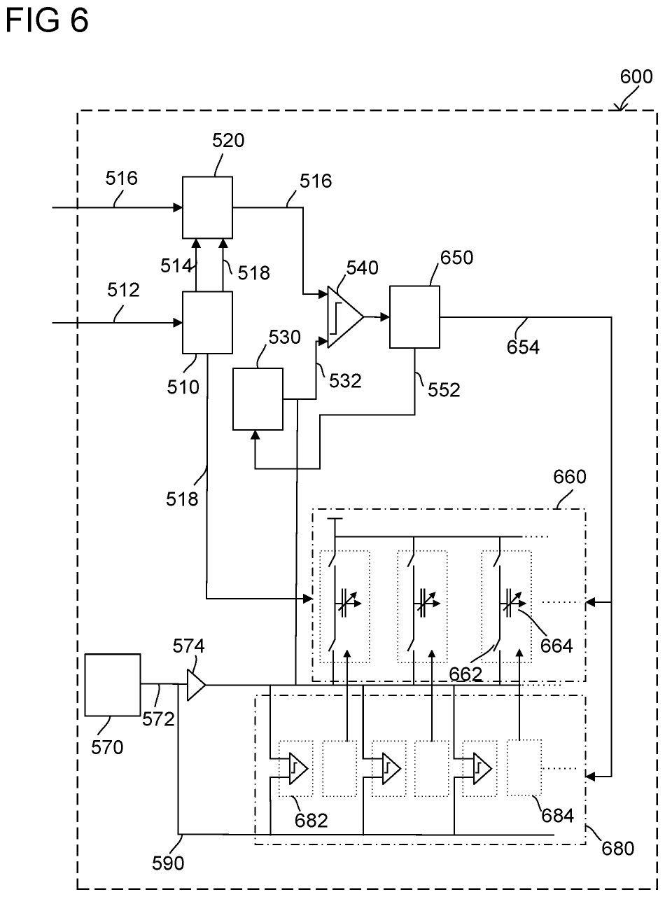

FIG. 6 shows an exemplary ADC 600 including a multi-cycle error correction circuit 680 according to some aspects.

The ADC 600 includes clock generator 510, sampling switch 520, digital-to-analog converter, DAC, 530, comparator 540, controller 650, capacitor bank 660, charge voltage source 570 and multi-cycle error correction circuit 680.

ADC 600 is similar to ADC 500, and includes a different error correction circuit 680 (instead of circuit 580) and a different capacitor bank 660 including variable/programmable (arrays of) capacitors.

The capacitor bank 660 of ADC 600 includes variable/programmable (arrays of) capacitors with switches 662. Controller 650 may be similar to controller 550 and is configured to control and synchronize multi-cycle error correction circuit 680. The other components of ADC 600 are configured in a similar way as the corresponding components of ADC 500.

The multi-cycle error correction circuit 680 is configured to detect and correct deviations over multiple sampling cycles, i.e. over the conversion of a plurality of analog input voltages 516.

Multi-cycle error correction circuit 680 includes a plurality of comparators 682 and loop filters 684. Multi-cycle error correction circuit 680 may include a comparator 682 and a loop filter 684 for a single event/bit, for multiple events/bits and/or for all of the events/bits occurring over multiple sampling cycles.

Multi-cycle error correction circuit 680 receives signal 654 from controller 650, which corresponds to delayed versions (Φ₀, Φ₁, . . . ; Φₙ) of events, i.e. of each bit processed by DAC 530. Each of the received signals is then compared to the voltage value of clean reference 590 via the plurality of comparators 682. Depending on the comparison result, the loop filters 684 are configured to adjust the corresponding variable (programmable) capacitors 664 of capacitor bank 660 in order to minimize reference voltage errors over multiple sampling clock cycles.

The multi-cycle error correction circuit 680 allows adjusting the values of the capacitors included in capacitor bank 660 to account for mismatches in the capacitor values, voltage reference values, supply voltage values, temperature changes or other effects.

In the case of a plurality of ADCs arranged in a time-interleaved (TI) manner, and sharing a common reference voltage source across all ADC slices, such as e.g. charge voltage source 270, 570 or 670, the reference voltage received by ADC slices may deteriorate (drop) due to crosstalk and/or droop.

In other words, the inner slices of a TI ADC arrangement/array may receive an erroneous (lower) reference voltage. The voltage error typically increases the further away an ADC slice is from the common reference voltage source.

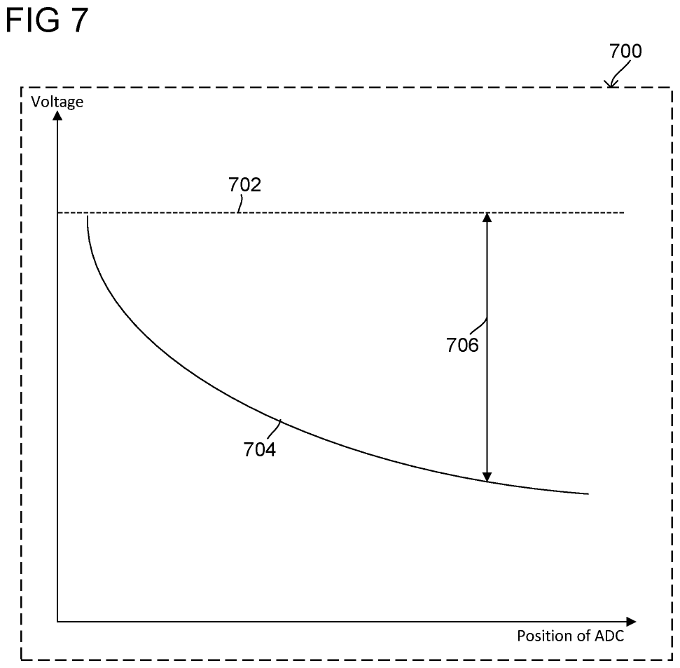

FIG. 7 shows a schematic overview of typical reference voltage errors in TI ADCs.

In the illustration of FIG. 7, 702 denotes the voltage level of the common reference voltage source of a TI ADC arrangement, and 704 denotes the voltage actually received by an ADC (slice). As can be seen in FIG. 7, the further away an ADC is from the common reference voltage source, the larger the error 706 becomes.

In the following, the above techniques, examples and embodiments to improve the settling of the reference voltage in an ADC are modified to an arrangement of TI ADCs including a plurality of ADCs. The modifications are applicable to a slice of a single ADC, across multiple slices or slice groups of a TI ADC, or across multiple unique ADCs in a larger system (multi-lane) sharing a common reference or references.

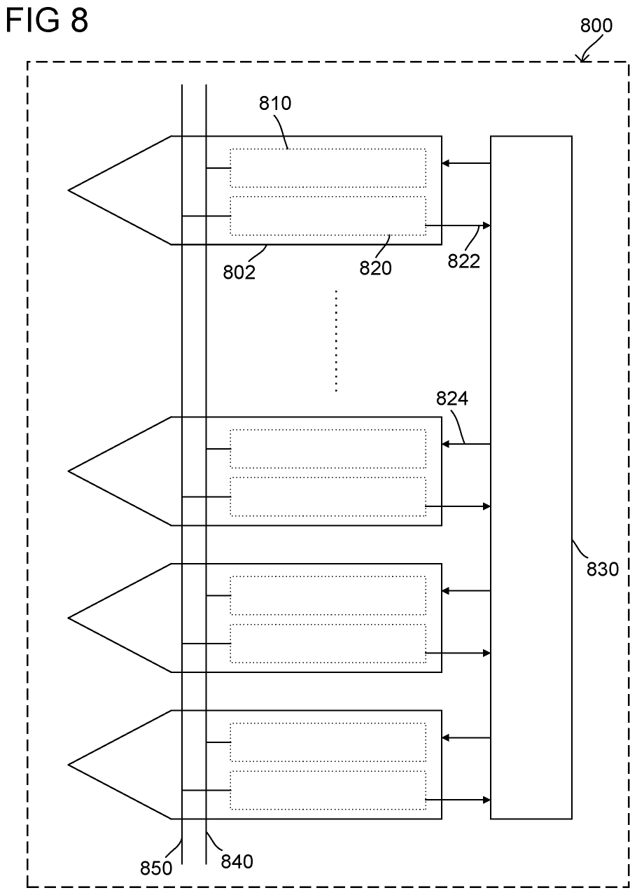

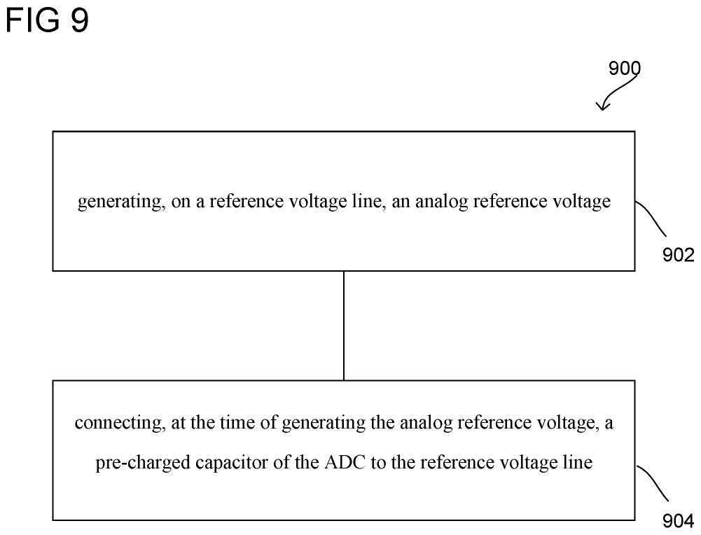

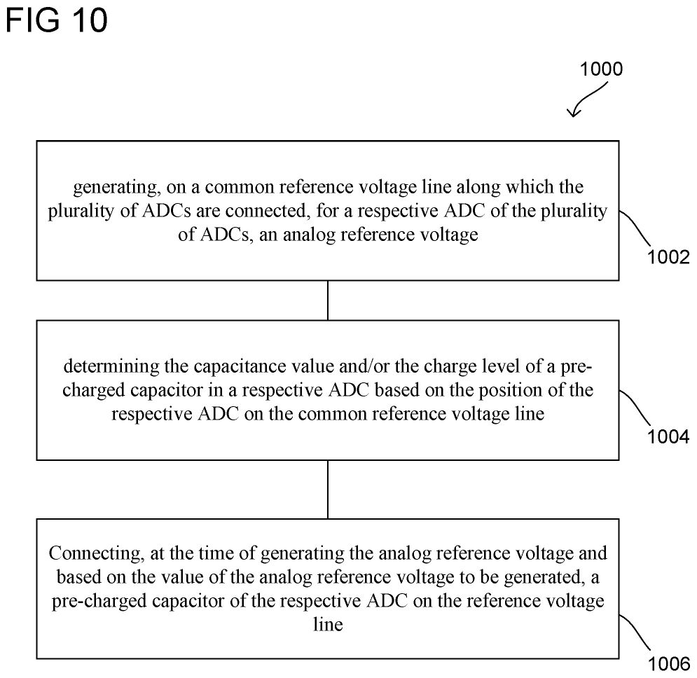

FIG. 8 illustrates an exemplary arrangement 800 including a plurality of TI ADCs 802 according to some aspects.

The arrangement 800 includes a plurality of ADCs 802, wherein each ADC 802 may be an ADC such as ADC 200 of FIG. 2, ADC 500 of FIG. 5 or ADC 600 of FIG. 6. Each ADC 802 is configured to include a fast recharge circuit 810, such as e.g. capacitor bank 260, 560 or 660. Each fast recharge circuit 810 includes at least one pre-charged capacitor (not shown in FIG. 8). The ADCs 802 further include an error correction circuits 820, such as e.g. error correction circuits 580 or 680.

A first reference voltage 840 is provided to each of the ADCs 802, and in particular to fast recharge circuit 810. Similarly to the exemplary embodiments of FIG. 5 and FIG. 6, a second (clean) reference voltage 850 is provided to each of the ADCs 802, and in particular to error corrections circuits 820, in order for the error corrections circuits 820 to be able to compare the two reference voltages.

A controller 830 is configured to control and synchronizes the operation of the plurality of ADCs. Controller 830 may include (dynamic) multi input, multi output control logic and loop filters. Controller 830 is configured to receive signals 822 from each of the error corrections circuits 820 of the plurality of TI ADCs. Controller 830 is further configured, based on the received signals 822, to determine the (optimal) value for the one or more pre-charged capacitors included in fast recharge circuits 810. The controller 830 is further configured to send a control signal 824 to one or more ADCs 802 instructing to select and connect onto the reference line one or more pre-charged capacitors included in fast recharge circuit 810. Controller 830 may be configured to directly connect the determined pre-charged capacitors, e.g. by controlling switches included in fast recharge circuit 810 (not shown in FIG. 8).

The controller 830 is further configured to, based on the location of an ADC in ADC arrangement 800, weight the corrective capacitors included in the fast recharge circuits 810 differently, in order to compensate for crosstalk/droop on the shared reference voltage 840 (as illustrated in FIG. 7).

The controller 830 is further configured to account for errors in neighboring ADCs slice and to adjust for errors along the arrangement/array dynamically over a plurality of sampling cycles.

In other words, in the arrangement 800 of FIG. 8, time aligned, data dependent feed-forward capacitors pre-charged to a higher voltage (or a charge pumped voltage) are switched onto the reference based upon synchronous (or asynchronous) data driven decision events occurring in ADC 802, speeding up the settling of the reference voltage with matched impulse currents, and reducing crosstalk for shared references across multiple ADC slices.

As an example, in a 5 nm technology implementation of the above TI ADC arrangement 800, a reference (active) buffer of an ADC slice may take up to 20 μm of the 200 μm total slice width. With the above arrangement 800, the area required by an active buffer is greatly reduced, e.g. by 50% or more, and the current needed by the active buffer may also be greatly reduced, e.g. by 50% or more.

FIG. 9 shows a flowchart illustrating a method 900 of settling of a reference voltage in an analog-to-digital converter, ADC. As shown in FIG. 9, the method 900 of settling a reference voltage includes generating 902, on a reference voltage line, an analog reference voltage, and connecting 904, at the time of generating the analog reference voltage, a pre-charged capacitor of the ADC to the reference voltage line to reduce a voltage error during the generation of the reference voltage.

FIG. 10 shows a flowchart illustrating a method 1000 of settling of a reference voltage in a plurality of time-interleaved analog-to-digital converters, ADCs, sharing a common reference voltage source. As shown in FIG. 10, the method 1000 includes generating 1002, on a common reference voltage line along which the plurality of ADCs are connected, for a respective ADC of the plurality of ADCs, an analog reference voltage; determining 1004 the capacitance value and/or the charge level of a pre-charged capacitor in a respective ADC based on the position of the respective ADC on the common reference voltage line, and connecting 1006, at the time of generating the analog reference voltage and based on the value of the analog reference voltage to be generated, a pre-charged capacitor of the respective ADC on the reference voltage line to reduce a voltage error during the generation of the reference voltage by the respective ADC.

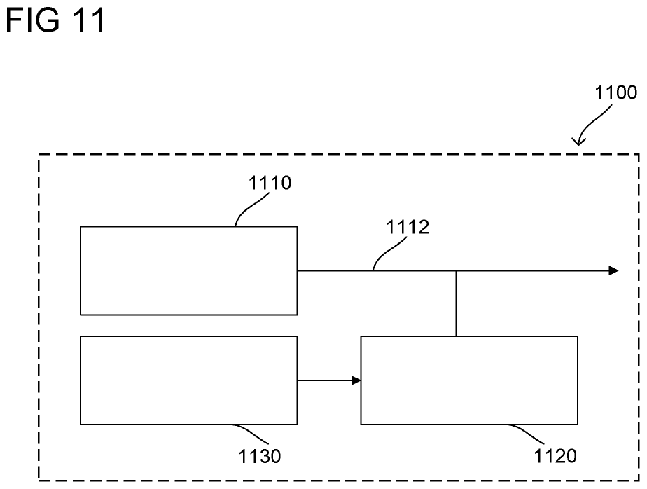

FIG. 11 illustrates an exemplary analog-to-digital converter, ADC, 1100 configured to convert an input analog voltage into a digital representation according to some aspects. As shown in FIG. 11, the ADC 1100 includes a digital-to-analog converter, DAC, 1110 configured to generate an analog reference voltage, wherein the analog reference voltage is generated on a reference voltage line 1112, a pre-charged capacitor 1120, and a controller 1130 configured to connect, at the time that the DAC 1110 generates the analog reference voltage, the pre-charged capacitor on the reference voltage line to reduce a voltage error during the generation of the analog reference voltage by the DAC 1110.

While the above descriptions and connected figures may depict electronic device components as separate elements, skilled persons will appreciate the various possibilities to combine or integrate discrete elements into a single element. Such may include combining two or more circuits to form a single circuit, mounting two or more circuits onto a common semiconductor chip or chassis to form an integrated element, executing discrete software components on a common processor core, etc. Conversely, skilled persons will recognize the possibility to separate a single element into two or more discrete elements, such as splitting a single circuit into two or more separate circuits, separating a semiconductor chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

The following examples disclose various aspects of this disclosure:

Example 1 is a method of settling of a reference voltage in an analog-to-digital converter, ADC. The method may include generating, on a reference voltage line, an analog reference voltage, and connecting, at the time of generating the analog reference voltage, a pre-charged capacitor of the ADC to the reference voltage line to reduce a voltage error during the generation of the reference voltage.

In Example 2, the subject-matter of Example 1 can optionally include that the capacitor is pre-charged to a higher voltage than the generated reference voltage, or to a voltage equal to the generated reference voltage.

In Example 3, the subject-matter of Examples 1 or 2 can optionally include selecting the pre-charged capacitor out of a plurality of pre-charged capacitors of the ADC based on the value of the analog reference voltage to be generated.

In Example 4, the subject-matter of Example 3 can optionally include that the plurality of capacitors have different capacitances and/or are pre-charged to different charge levels.

In Example 5, the subject-matter of any of Examples 1 to 4 can optionally include that the ADC includes a digital-to-analog converter, DAC, configured to receive a digital code indicative of the analog reference voltage to be generated and to generate the analog reference voltage, and that the pre-charged capacitor is connected to the reference voltage line at the time that the DAC generates the analog reference voltage.

In Example 6, the subject-matter of any one of Examples 1 to 5 can optionally include that the digital code corresponds to a digital approximation of an analog input voltage to be converted by the ADC.

In Example 7, the subject-matter of any one of Examples 1 to 6 can optionally include that the ADC includes a successive-approximation register, SAR, configured to store successively a plurality of digital codes, and that each digital code stored in the SAR is indicative of an analog reference voltage to be generated, and corresponds to successive approximations of an input analog voltage to be converted by the ADC.

In Example 8, the subject-matter of any one of Examples 1 to 7 can optionally include receiving a further reference voltage, comparing the value of the generated reference voltage to the value of the further reference voltage, and in case the generated reference voltage value does not correspond to an expected value based on the value of the further reference voltage, adjusting the generated reference voltage in accordance with the further reference voltage value.

In Example 9, the subject-matter of Example 8 can optionally include receiving a sampling clock signal indicative of the start of a conversion of an analog input voltage into a digital representation by the ADC, and adjusting the generated reference voltage during a sampling clock cycle.

In Example 10, the subject-matter of Example 8 can optionally include receiving a sampling clock signal indicative of the start of a conversion of an analog input voltage into a digital representation by the ADC, and adjusting the generated reference voltage over multiple sampling clock cycles spanning multiple conversions of analog input voltages by the ADC.

In Example 11, the subject-matter of Examples 9 or 10 can optionally include receiving a reset signal prior to the sampling clock signal, wherein the reset signal is indicative of a reset phase of the ADC prior to the conversion of a next analog input voltage.

Example 12 is a method of settling a reference voltage in a plurality of time-interleaved analog-to-digital converters, ADCs, sharing a common reference voltage source. The method may include generating, on a common reference voltage line along which the plurality of ADCs are connected, for a respective ADC of the plurality of ADCs, an analog reference voltage, and connecting, at the time of generating the analog reference voltage and based on the value of the analog reference voltage to be generated, a pre-charged capacitor of the respective ADC on the reference voltage line to reduce a voltage error during the generation of the reference voltage by the respective ADC, wherein the capacitance value and/or the charge level of the pre-charged capacitor in a respective ADC is determined based on the position of the respective ADC on the common reference voltage line.

In Example 13, the subject-matter of Example 12 can optionally include selecting the pre-charged capacitor out of a plurality of pre-charged capacitors of a respective ADC based on the value of the analog reference voltage to be generated.

In Example 14, the subject-matter of Examples 12 or 13 can optionally include adjusting the generated analog reference voltage in a respective ADC based on a comparison result of the generated reference voltage value to a further reference voltage value.

Example 15 is an analog-to-digital converter, ADC, configured to convert an input analog voltage into a digital representation. The ADC may include a digital-to-analog converter, DAC, configured to generate an analog reference voltage, wherein the analog reference voltage is generated on a reference voltage line, a pre-charged capacitor, and a controller configured to connect, at the time that the DAC generates the analog reference voltage, the pre-charged capacitor on the reference voltage line to reduce a voltage error during the generation of the analog reference voltage by the DAC.

In Example 16, the subject-matter of Example 15 can optionally include that the DAC is further configured to receive a digital code indicative of the analog reference voltage to be generated, wherein the digital code corresponds to a digital approximation of the analog input voltage to be converted by the ADC.

In Example 17, the subject-matter of Examples 15 or 16 can optionally include a comparator configured to compare the input analog voltage to the generated reference voltage, and a controller configured to receive the result of the comparison, and to determine, based on the result of comparison, a digital code indicative of the analog reference voltage to be generated.

In Example 18, the subject-matter of any one of Examples 15 to 17 can optionally include a successive-approximation register, SAR, configured to store successively a plurality of digital codes, wherein each digital code stored in the SAR is indicative of an analog reference voltage to be generated, and corresponds to successive approximations of the input analog voltage to be converted by the ADC.

In Example 19, the subject-matter of any one of Examples 15 to 18 can optionally include that the capacitor is pre-charged via a voltage booster.

In Example 20, the subject-matter of any one of Examples 15 to 19 can optionally include that the capacitor is pre-charged to a higher voltage than the generated reference voltage, or to a voltage equal to the generated reference voltage.

In Example 21, the subject-matter of any one of Examples 15 to 20 can optionally include a plurality of pre-charged capacitors, wherein the pre-charged capacitor connected on the reference voltage line is selected out of the plurality of pre-charged capacitors based on the value of the analog reference voltage to be generated.

In Example 22, the subject-matter of any one of Examples 15 to 21 can optionally include that the plurality of pre-charged capacitors have different capacitances and/or are pre-charged to different charge levels.

In Example 23, the subject-matter of any one of Examples 15 to 22 can optionally include that the DAC is an algorithmically-weighted capacitive DAC, or that the DAC is a binary-weighted capacitive DAC.

In Example 24, the subject-matter of any one of Examples 15 to 23 can optionally include that connecting the pre-charged capacitor on the reference voltage line is performed by actuating a switch between the pre-charged capacitor and the reference voltage line.

In Example 25, the subject-matter of any one of Examples 15 to 24 can optionally include that the ADC is configured to receive a sampling clock signal indicative of the start of the conversion of the analog input voltage by the ADC, and that the ADC further includes a comparator configured to compare the value of the generated reference voltage after the pre-charged capacitor is connected on the reference voltage line to a value of a further reference voltage, and an error correction circuit configured to: receive a signal indicative of the result of the comparison from the comparator, and based on the result of the comparison, adjust the generated reference voltage.

In Example 26, the subject-matter of Example 25 can optionally include that the error correction circuit includes a plurality of capacitors, and that, based on the result of the comparison, the error correction circuit is configured to connect, during a sampling clock cycle, one or more capacitors out of the plurality of capacitors on the reference voltage line.

In Example 27, the subject-matter of Example 25 can optionally include that the pre-charged capacitor is a variable capacitor, and that the error correction circuit includes a plurality of loop filters, and is configured to adjust the generated reference voltage by adjusting the capacitance value and/or the charge level of the pre-charged capacitor over multiple sampling clock cycles spanning multiple conversions of analog input voltages by the ADC.

In Example 28, the subject-matter of any one of Examples 25 to 27 can optionally include a sampling switch configured to receive a reset signal prior to the sampling clock signal, and to reset the sampling switch by switching it off.

Example 29 is an arrangement including a plurality of ADCs according to the subject-matter of any one of Examples 15 to 28. The subject-matter of Example 29 includes that said plurality of ADCs are time-interleaved and share a common reference voltage source and a common reference voltage line, and that the capacitance values and/or the charge levels of the pre-charged capacitors included in each ADC are determined based on the position of an ADC along the common reference voltage line.

In Example 30, the subject-matter of Example 29 can optionally include that each respective ADC further includes a plurality of pre-charged capacitors, and that the pre-charged capacitor of a respective ADC connected on the reference voltage line is selected out of the plurality of pre-charged capacitors based on the value of the analog reference voltage to be generated.

In Example 31, the subject-matter of Examples 29 or 30 can optionally include a controller configured to adjust the value of the generated analog reference voltage in a respective ADC based on a comparison result of the generated reference voltage to a further reference voltage.

In Example 32, the subject-matter of Example 31 can optionally include that the arrangement is further configured to receive a sampling clock signal indicative of the start of a conversion of an analog input voltage by a respective ADC, that the pre-charged capacitor included in the respective ADC is variable, and that the controller is further configured, based on the result of the comparison, to adjust the generated reference voltage of the respective ADC over multiple sampling clock cycles by adjusting the capacitance value and/or the charge value of the pre-charged capacitor of the respective ADC.

Example 33 is a non-transitory computer readable medium. The non-transitory computer readable medium may include instructions which, when executed by one or more processors, are configured to cause the one or more processors to implement a method of settling of a reference voltage in an analog-to-digital converter, ADC, wherein the method includes generating, on a reference voltage line, an analog reference voltage, and connecting, at the time of generating the analog reference voltage, a pre-charged capacitor of the ADC to the reference voltage line to reduce a voltage error during the generation of the reference voltage.

In Example 34, the subject-matter of Example 33 can optionally include that the capacitor is pre-charged to a higher voltage than the generated reference voltage, or that the capacitor is pre-charged to a voltage equal to the generated reference voltage.

In Example 35, the subject-matter of Examples 33 or 34 can optionally include that the instructions are further configured to cause the one or more processors to: select the pre-charged capacitor out of a plurality of pre-charged capacitors of the ADC based on the value of the analog reference voltage to be generated.

In Example 36, the subject-matter of Example 35 can optionally include that the plurality of capacitors have different capacitances and/or are pre-charged to different charge levels.

In Example 37, the subject-matter of any one of Examples 33 to 36 can optionally include that the ADC includes a digital-to-analog converter, DAC, configured to receive a digital code indicative of the analog reference voltage to be generated and to generate the analog reference voltage, and that the pre-charged capacitor is connected to the reference voltage line at the time that the DAC generates the analog reference voltage.

In Example 38, the subject-matter of Example 37 can optionally include that the digital code corresponds to a digital approximation of an analog input voltage to be converted by the ADC.

In Example 39, the subject-matter of any one of Examples 33 to 38 can optionally include that the ADC includes a successive-approximation register, SAR, configured to store successively a plurality of digital codes, and that each digital code stored in the SAR is indicative of an analog reference voltage to be generated, and corresponds to successive approximations of an input analog voltage to be converted by the ADC.

In Example 40, the subject-matter of any one of Examples 33 to 39 can optionally include that the instructions are further configured to cause the one or more processors to receive a further reference voltage, compare the value of the generated reference voltage to the value of the further reference voltage, and in case the generated reference voltage value does not correspond to an expected value based on the value of the further reference voltage, adjust the generated reference voltage in accordance with the further reference voltage value.

In Example 41, the subject-matter of Example 40 can optionally include that the instructions are further configured to cause the one or more processors to receive a sampling clock signal indicative of the start of a conversion of an analog input voltage into a digital representation by the ADC and to adjust the generated reference voltage during a sampling clock cycle.

In Example 42, the subject-matter of Example 40 can optionally include that the instructions are further configured to cause the one or more processors to receive a sampling clock signal indicative of the start of a conversion of an analog input voltage into a digital representation by the ADC, and to adjust the generated reference voltage over multiple sampling clock cycles spanning multiple conversions of analog input voltages by the ADC.

In Example 43, the subject-matter of Examples 41 or 42 can optionally include that the instructions are further configured to cause the one or more processors to receive a reset signal prior to the sampling clock signal, wherein the reset signal is indicative of a reset phase of the ADC prior to the conversion of a next analog input voltage.

Example 44 is a non-transitory computer readable medium. The non-transitory computer readable medium may include instructions which, when executed by one or more processors, are configured to cause the one or more processors to implement a method of settling a reference voltage in a plurality of time-interleaved analog-to-digital converters, ADCs, sharing a common reference voltage source, wherein the method includes generating, on a common reference voltage line along which the plurality of ADCs are connected, for a respective ADC of the plurality of ADCs, an analog reference voltage, and connecting, at the time of generating the analog reference voltage, a pre-charged capacitor of the respective ADC on the reference voltage line to reduce a voltage error during the generation of the reference voltage by the respective ADC, wherein the capacitance value and/or the charge level of the pre-charged capacitor in a respective ADC is determined based on the position of the respective ADC on the common reference voltage line.

In Example 45, the subject-matter of Example 44 can optionally include that the instructions are further configured to cause the one or more processors to select the pre-charged capacitor out of a plurality of pre-charged capacitors of a respective ADC based on the value of the analog reference voltage to be generated.

In Example 46, the subject-matter of Examples 44 or 45 can optionally include that the instructions are further configured to cause the one or more processors to adjust the generated analog reference voltage in a respective ADC based on a comparison result of the generated reference voltage value to a further reference voltage value.

Example 47 is an analog-to-digital converter, ADC, configured to convert an input analog voltage into a digital representation. The ADC may include means for generating an analog reference voltage, wherein the analog reference voltage is generated on a reference voltage line, and means for connecting a pre-charged capacitor of the ADC, at the time that the analog reference voltage is generated, on the reference voltage line to reduce a voltage error during the generation of the analog reference voltage.

In Example 48, the subject-matter of Example 47 can optionally include means for receiving a digital code indicative of the analog reference voltage to be generated, wherein the digital code corresponds to a digital approximation of the analog input voltage to be converted by the ADC.

In Example 49, the subject-matter of Examples 47 or 48 can optionally include means for comparing the input analog voltage to the generated reference voltage, means for receiving the result of the comparison, and means for determining, based on the result of comparison, a digital code indicative of the analog reference voltage to be generated.

In Example 50, the subject-matter of any one of Examples 47 to 49 can optionally include means for storing a plurality of digital codes, wherein each stored digital code stored is indicative of an analog reference voltage to be generated, and corresponds to successive approximations of the input analog voltage to be converted by the ADC.

In Example 51, the subject-matter of any one of Examples 47 to 50 can optionally include that the capacitor is pre-charged via a voltage booster.

In Example 52, the subject-matter of any one of Examples 47 to 51 can optionally include that the capacitor is pre-charged to a higher voltage than the generated reference voltage, or to a voltage equal to the generated reference voltage.

In Example 53, the subject-matter of any one of Examples 47 to 52 can optionally include a plurality of pre-charged capacitors, and means for selecting the pre-charged capacitor connected on the reference voltage line out of the plurality of pre-charged capacitors based on the value of the analog reference voltage to be generated.

In Example 54, the subject-matter of any one of Examples 47 to 53 can optionally include that the plurality of pre-charged capacitors have different capacitances and/or are pre-charged to different charge levels.

In Example 55, the subject-matter of any one of Examples 47 to 54 can optionally include means for receiving a sampling clock signal indicative of the start of the conversion of the analog input voltage by the ADC, means for comparing the value of the generated reference voltage after the pre-charged capacitor is connected on the reference voltage line to a value of a further reference voltage, means for receiving a signal indicative of the result of the comparison, and means for adjusting the generated reference voltage, based on the result of the comparison.

In Example 56, the subject-matter of Example 55 can optionally include means for connecting one or more capacitors out of the plurality of capacitors on the reference voltage line, wherein the one or more capacitors are connected during a sampling clock cycle and based on the result of the comparison.

In Example 57, the subject-matter of Example 55 can optionally include means for adjusting the generated reference voltage by adjusting the capacitance value and/or the charge level of the pre-charged capacitor over multiple sampling clock cycles spanning multiple conversions of analog input voltages by the ADC.

In Example 58, the subject-matter of any one of Examples 47 to 57 can optionally include that said plurality of ADCs are time-interleaved and share a common reference voltage source and a common reference voltage line, and that the capacitance values and/or the charge levels of the pre-charged capacitors included in each ADC are determined based on the position of an ADC along the common reference voltage line.

In Example 59, the subject-matter of Example 58 can optionally include that each respective ADC further includes a plurality of pre-charged capacitors, and include means for selecting the pre-charged capacitor of a respective ADC connected on the reference voltage line out of the plurality of pre-charged capacitors based on the value of the analog reference voltage to be generated.

In Example 60, the subject-matter of Examples 58 or 59 can optionally include means for adjusting the value of the generated analog reference voltage in a respective ADC based on a comparison result of the generated reference voltage to a further reference voltage.

In Example 61, the subject-matter of Example 60 can optionally include means for receiving a sampling clock signal indicative of the start of a conversion of an analog input voltage by a respective ADC, and means for adjusting, based on the result of the comparison, the generated reference voltage of the respective ADC over multiple sampling clock cycles by adjusting the capacitance value and/or charge level of the pre-charged capacitor of the respective ADC.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A non-transitory computer readable medium comprising instructions which, when executed by one or more processors, are configured to cause the one or more processors to:
generate, on a reference voltage line, an analog reference voltage; and
connect, at a time of generating the analog reference voltage, a pre-charged capacitor of an analog-to-digital converter (ADC) to the reference voltage line to reduce a voltage error during a generation of the analog reference voltage in the ADC.

2. The non-transitory computer readable medium of claim 1, wherein the instructions further cause the one or more processors to select the pre-charged capacitor out of a plurality of pre-charged capacitors of the ADC based on the value of the analog reference voltage to be generated.

3. The non-transitory computer readable medium of claim 1,
wherein the ADC comprises a digital-to-analog converter (DAC) configured to receive a digital code indicative of the analog reference voltage to be generated and to generate the analog reference voltage, and
wherein the pre-charged capacitor is connected to the reference voltage line at the time that the DAC generates the analog reference voltage.

4. The non-transitory computer readable medium of claim 1, wherein the instructions further cause the one or more processors to:
receive a further reference voltage;
compare the value of the analog reference voltage to the value of the further reference voltage; and
in case the analog reference voltage value does not correspond to an expected value based on the value of the further reference voltage, adjust the analog reference voltage in accordance with the further reference voltage value.

5. A method of settling a reference voltage in a plurality of time-interleaved analog-to-digital converters (ADCs) sharing a common reference voltage source, the method comprising:
generating, on a common reference voltage line along which the plurality of ADCs are connected, for a respective ADC of the plurality of ADCs, an analog reference voltage; and
connecting, at the time of generating the analog reference voltage and based on the value of the analog reference voltage to be generated, a pre-charged capacitor of the respective ADC to the reference voltage line to reduce a voltage error during the generation of the analog reference voltage by the respective ADC,
wherein the capacitance value and/or the charge level of the pre-charged capacitor in a respective ADC is determined based on the position of the respective ADC on the common reference voltage line.

6. The method of claim 5, further comprising:
selecting the pre-charged capacitor out of a plurality of pre-charged capacitors of a respective ADC based on the value of the analog reference voltage to be generated.

7. The method of claim 5, further comprising:
adjusting the generated analog reference voltage in a respective ADC based on a comparison result of the generated analog reference voltage value to a further reference voltage value.

8. An analog-to-digital converter (ADC) configured to convert an input analog voltage into a digital representation, the ADC comprising:
a digital-to-analog converter (DAC) configured to generate an analog reference voltage on a reference voltage line;
a pre-charged capacitor; and
a controller configured to:
connect, during a generation of the analog reference voltage by the DAC, the pre-charged capacitor to the reference voltage line to reduce a voltage error during the generation of the analog reference voltage by the DAC.

9. The ADC of claim 8, further comprising:
a comparator configured to compare the input analog voltage to the analog reference voltage; and
a controller configured to receive the result of the comparison, and to determine, based on the result of comparison, a digital code indicative of the analog reference voltage to be generated.

10. The ADC of claim 8, further comprising:
a successive-approximation register (SAR) configured to store successively a plurality of digital codes,
wherein each digital code stored in the SAR is indicative of the analog reference voltage to be generated, and corresponds to successive approximations of the input analog voltage to be converted by the ADC.

11. The ADC of claim 8, wherein the capacitor is pre-charged via a voltage booster.

12. The ADC of claim 8, further comprising:
a plurality of pre-charged capacitors,
wherein the pre-charged capacitor connected to the reference voltage line is selected out of the plurality of pre-charged capacitors based on the value of the analog reference voltage to be generated.

13. The ADC of claim 12, wherein the plurality of pre-charged capacitors have different capacitances and/or are pre-charged to different charge levels.

14. The ADC of claim 8, further configured to receive a sampling clock signal indicative of the start of the conversion of the analog input voltage by the ADC, and further comprising:
a comparator configured to compare the value of the analog reference voltage after the pre-charged capacitor is connected to the reference voltage line to a value of a further reference voltage; and
an error correction circuit configured to:
receive a signal indicative of the result of the comparison from the comparator; and
based on the result of the comparison, adjust the analog reference voltage.

15. The ADC of claim 14,
wherein the error correction circuit comprises a plurality of capacitors, and
wherein, based on the result of the comparison, the error correction circuit is configured to connect, during a sampling clock cycle, one or more capacitors out of the plurality of capacitors to the reference voltage line.

16. The ADC of claim 14,
wherein the pre-charged capacitor is a variable capacitor, and
wherein the error correction circuit comprises a plurality of loop filters, and is configured to adjust the analog reference voltage by adjusting the capacitance value and/or the charge level of the pre-charged capacitor over multiple sampling clock cycles spanning multiple conversions of analog input voltages by the ADC.

17. A system comprising:
a plurality of ADCs, wherein each ADC of the plurality of ADCs comprises the ADC of claim 8,
wherein the plurality of ADCs are time-interleaved and share a common reference voltage source and a common reference voltage line, and
wherein the capacitance values and/or the charge levels of the pre-charged capacitors comprised in each ADC are determined based on the position of an ADC along the common reference voltage line.

18. The arrangement of claim 17, wherein each respective ADC of the plurality of ADCs further comprises:
a plurality of pre-charged capacitors associated with the respective ADC, and
wherein the pre-charged capacitor of the respective ADC connected to the reference voltage line is selected from the plurality of pre-charged capacitors based on the value of the analog reference voltage to be generated.

19. The system of claim 18, further comprising:
a controller configured to adjust the value of the analog reference voltage in the respective ADC based on a comparison result of the analog reference voltage to a further reference voltage.

20. The system of claim 19, further configured to receive a sampling clock signal indicative of the start of a conversion of an analog input voltage by the respective ADC,
wherein the pre-charged capacitor comprised in the respective ADC is variable, and
wherein the controller is further configured, based on the result of the comparison, to adjust the analog reference voltage of the respective ADC over multiple sampling clock cycles by adjusting the capacitance value and/or the charge value of the pre-charged capacitor of the respective ADC.
